(19) United States
(12) Patent Application Publication
(10) Pub. No.: US 2025/0251231 A1
(43) Pub. Date: Aug. 7, 2025

(54) MEASUREMENT PROBE HEAD TEMPERATURE COMPENSATION

(71) Applicant: Hexagon Metrology, Inc., North Kingstown, RI (US)

(72) Inventors: Ingo Lindner, Wetzlar (DE); Milan Kocic, Pawtucket, RI (US)

(21) Appl. No.: 19/045,735

(22) Filed: Feb. 5, 2025

Related U.S. Application Data
(60) Provisional application No. 63/550,505, filed on Feb. 6, 2024.

(51) Int. Cl. G01B 5/016; G01D 5/20; G01D 18/00; G01K 7/36

(52) U.S. Cl. CPC G01B 5/016; G01D 5/2013; G01D 18/00; G01K 7/36

(57) ABSTRACT

A measurement probe temperature compensation system for a coordinate measurement machine may include a measurement probe configured to measure a workpiece on the coordinate measurement machine and a magnetic sensor associated with the measurement probe. The measurement probe has a plurality of positional offsets at a plurality of different ambient temperatures. The magnetic sensor is configured to emit a magnetic signal based on a current ambient temperature in response to receipt of a magnetic field.

### PRIORITY

This patent application claims priority from U.S. Provisional Patent Application No. 63/550,505, filed Feb. 6, 2024, entitled MEASUREMENT PROBE HEAD COMPENSATION and naming Ingo Lindner, Milan Kocic, and Damien Carron as the inventors, the disclosure of which is incorporated herein in its entirety, by reference.

This patent application is also related to U.S. patent application Ser. No. 19/039,175, filed Jan. 28, 2025, entitled MEASUREMENT PROBE HEAD IDENTIFICATION and naming Ingo Lindner and Milan Kocic as the inventors, and U.S. patent application entitled MEASUREMENT PROBE RACK WEIGHT COMPENSATION, filed Feb. 5, 2025 and naming Ingo Lindner and Milan Kocic as the inventors, the disclosure of each of which are incorporated herein in its entirety, by reference.

### FIELD

Illustrative embodiments of the invention generally relate to coordinate measuring machines (CMMs) and, more particularly, various embodiments of the invention relate to temperature compensation applied to CMM probes.

### BACKGROUND

Coordinate measuring machines (“CMMs”, also known as surface scanning measuring machines) measure geometry and surface profiles or verify the topography of known surfaces. For example, a CMM may measure the topological profile of a propeller to ensure that its surface is appropriately sized and shaped for its specified task (e.g., moving a 24 foot boat at pre-specified speeds through salt water). To that end, conventional CMMs often have a base supporting a workpiece to be measured. The base is directly connected with and supporting a movable assembly having a probe that directly contacts and moves along a surface of a workpiece being measured. CMMs represent a gold standard for accurately measuring a wide variety of different types of workpieces. For example, CMMs can measure critical dimensions of aircraft engine components, surgical tools, and machine parts. Precise and accurate measurements help ensure that their underlying systems, such as an aircraft in the case of aircraft components, operate as specified. Some workpieces are measured to a fine precision, such as on the micron level. The accuracy of a CMM may depend, in part, on the measuring device (e.g., probe/stylus) used for the measurement, where many such probes and stylii may be available.

### SUMMARY OF VARIOUS EMBODIMENTS

In accordance with one embodiment of the invention, a measurement probe temperature compensation system for a coordinate measurement machine may include a measurement probe configured to measure a workpiece on the coordinate measurement machine and a magnetic sensor associated with the measurement probe. The measurement probe has a plurality of positional offsets at a plurality of different ambient temperatures. The magnetic sensor is configured to emit a magnetic signal based on a current ambient temperature in response to receipt of a magnetic field.

In accordance with other embodiments, the measurement probe temperature compensation system may also include a reader configured to receive the magnetic signal and convert the magnetic signal into a magnetic signature, the reader configured to determine a determined positional offset of the probe as a function of the magnetic signature, the determined positional offset being one of the plurality of positional offsets.

In accordance with other embodiments, the reader may include a coil to detect the magnetic signal.

In accordance with other embodiments, the reader is configured to determine a current positional offset of the probe in response to the magnetic sensor is proximate to the coil.

In accordance with other embodiments, the magnetic reader may include a passive portion configured to receive the magnetic signal and an active portion configured to emit the magnetic field toward the magnetic sensor.

In accordance with other embodiments, the active portion uses magnetic induction to produce the magnetic signal received by the passive portion.

In accordance with other embodiments, the reader may include a memory device, configured to store the plurality of positional offsets cross referenced to a plurality of magnetic signatures for the probe, where each positional offset corresponds to a magnetic signature at a different ambient temperature and a processor, coupled to the memory device.

In accordance with other embodiments, the processor is configured to determine a current positional offset for the magnetic signature, where the current positional offset corresponds to the current ambient temperature.

In accordance with other embodiments, the processor communicates the current positional offset to the coordinate measurement machine, and in response the coordinate measurement machine adjusts measurement data of the workpiece by the current positional offset.

In accordance with other embodiments, the current positional offset may include one or more of an x-axis, a y-axis, or a z-axis amount.

In accordance with another embodiment of the invention, a method of determining a temperature compensation offset for a coordinate measurement machine may include providing a measurement probe comprising a magnetic sensor, the measurement probe configured to be used with the coordinate measurement machine and emitting a magnetic field toward the measurement probe to cause the measurement probe to produce a magnetic signal in response to receipt of the magnetic field, the measurement probe having a plurality of positional offsets at a plurality of different ambient temperatures.

In accordance with another embodiment of the invention, a computer program product for use on a computer system for determining a temperature compensation offset for a tactile stylus attached to a distal end of a measurement probe of a coordinate measurement machine, the computer program product comprising a tangible, non-transient computer usable medium having computer readable program code thereon. The computer readable program code may include program code for causing emission of a magnetic field toward a magnetic sensor of the measurement probe to cause the magnetic sensor to produce a magnetic signal and program code for converting the magnetic signal into a magnetic signature, the measurement probe having a plurality of positional offsets at a plurality of different ambient temperatures.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1A schematically shows a diagram illustrating a representative coordinate measurement machine (CMM) in accordance with illustrative embodiments.

FIG. 1B schematically shows an interface panel that may be used with the coordinate measuring machine in accordance with illustrative embodiments.

FIG. 2 schematically shows a probe rack diagram in accordance with illustrative embodiments.

FIG. 3 schematically shows a detachable probe in accordance with illustrative embodiments.

FIG. 4 schematically shows a stylus rack in accordance with illustrative embodiments.

FIG. 5 schematically shows a stylus in accordance with illustrative embodiments.

FIG. 6 schematically shows an uncompensated CMM measurement process in accordance with illustrative embodiments.

FIG. 7 schematically shows a sensor system in accordance with illustrative embodiments.

FIG. 8A schematically shows an exemplary X-axis compensation diagram vs. temperature in accordance with illustrative embodiments.

FIG. 8B schematically shows an exemplary Y-axis compensation diagram vs. temperature in accordance with illustrative embodiments.

FIG. 8C schematically shows an exemplary Z-axis compensation diagram vs. temperature in accordance with illustrative embodiments.

FIG. 9 shows a probe/stylus compensation table in accordance with illustrative embodiments.

FIG. 10 shows a block diagram of an exemplary probe temperature compensation system in accordance with illustrative embodiments.

FIG. 11 schematically shows a compensated CMM measurement process in accordance with illustrative embodiments.

FIG. 12 schematically shows an obtain positional offsets at a current ambient temperature process in accordance with illustrative embodiments.

### DESCRIPTION OF ILLUSTRATIVE EMBODIMENTS

In illustrative embodiments, a coordinate measuring machine (CMM) may utilize a number of different probes of different types for various measurement tasks involving varied workpieces. The probes may include a number of tactile or optical probes that measure the workpiece. Tactile probes include a probe body and a removable stylus that includes one or more stylus tips. The stylus may be constructed of one or more materials that may experience minor deflection under various ambient temperatures. Deflections may be significant enough to meaningfully deflect the stylus tip and produce inaccurate measurements of the workpiece. Various embodiments may provide temperature compensation for probes/stylii by providing a sensitive magnetic sensor in the probe body. When a sensor is about to be used or during use, the system obtains a magnetic signature from the stylus that corresponds to the current ambient temperature and determines a deflection of the stylus tip. As the coordinate measurement machine obtains measurements of the workpiece(s), the coordinate measurement machine applies the deflection to the actual measurements, thus producing temperature-compensated workpiece measurements. Details are discussed below.

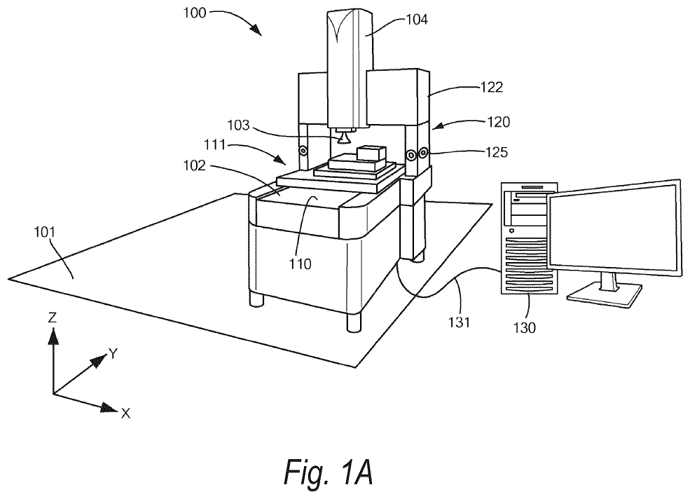

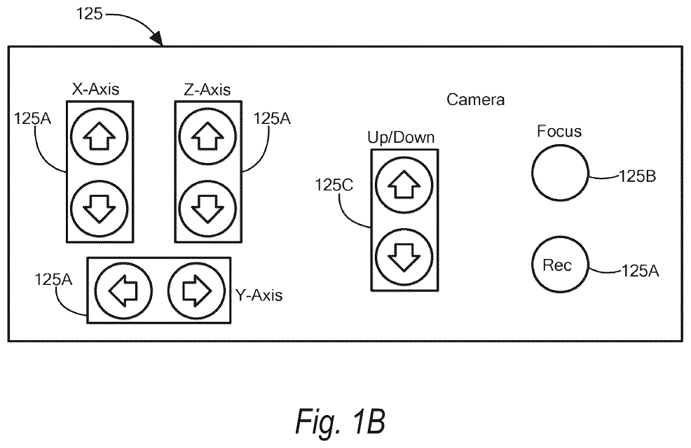

FIG. 1A schematically shows a representative coordinate measurement machine (CMM) 100 in accordance with illustrative embodiments. As known by those of skill in the art, the CMM 100, which is supported on a floor 101 in this illustration, measures a workpiece 111 on its bed/table/base (referred to as “base 102”). Generally, the base 102 of the CMM 100 defines an X-Y plane 110 parallel to the plane of the floor 101.

To measure a workpiece 111 on its base 102, the CMM 100 has movable features 122 arranged to move a measuring device 103, such as a mechanical, tactile probe (e.g., a touch trigger or a scanning probe in a standard CMM 100), a non-contact probe (e.g., using laser probes), and/or a camera (e.g., a machine-vision CMM 100), coupled with a movable arm 104.

Alternately, some embodiments move the base 102 with respect to a stationary measuring device 103. Either way, the movable features 122 of the CMM 100 manipulate the relative positions of the measuring device 103 and the workpiece 111 (or calibration artifact) with respect to one another to obtain the desired measurement. Accordingly, the CMM 100 can measure locations of a variety of features of the workpiece or artifact 111. The CMM 100 has a motion and data control system 120 that controls and coordinates its movements and activities.

Among other things, the control system 120 may include a computing device 130 and the noted sensors/movable features 122. The computing device 130 may include a microprocessor, programmable logic, firmware, advance control, acquisition algorithms, and analysis algorithms. The computing device 130 may have on-board digital memory (e.g., RAM or ROM) for storing data and/or computer code, including instructions for implementing some or all the control system operations and methods. Alternately, or in addition, the computing device 130 may be operably coupled to other digital memory, such as RAM or ROM, or a programmable memory circuit for storing such computer code, measurement data, and/or control data.

Among other things, the computing device 130 may be a desktop computer, a tower computer, or a laptop computer, a tablet computer or a pad computing device, a smart phone, a smart watch, or any other form a wearable computer. The computing device 130 may be coupled to the CMM 100 via a hardwired connection, such as an Ethernet cable 131, or via a wireless link, such as a Bluetooth or a WiFi link. The computing device 130 may, for example, include software to control the CMM 100 during use or calibration, and/or may include software configured to process data acquired during a calibration process (e.g., Hexagon PC-DMIS Pro, PC-DMIS CAD, or PC-DMIS CAD++). In addition, the computing device 130 may include a user interface configured to allow a user to manually operate the CMM 100.

Because their relative positions are determined by the action of the movable features 122, the CMM 100 may be considered as having “knowledge” about data relating to the relative locations of the base 102, and the workpiece or artifact 111, with respect to its measuring device 103. More particularly, the computing device 130 controls and stores information about the motions of the movable features 122. Alternately, or in addition, the movable features 122 of some embodiments may include sensors that sense the locations of the table and/or measuring device 103, and probes, and report that data to the computing device 130. The information about the motions and positions of the table and/or measuring device 103 of the CMM 100 may be recorded in terms of a two-dimensional (e.g., X-Y; X-Z; Y-Z) or three-dimensional (X-Y-Z) coordinate system referenced to a point on the CMM 100. The CMM 100 may also include a user interface 125 that may allow a user to start operation, stop operation, make adjustments, and the like.

FIG. 1B schematically shows a user interface panel that may be used with the coordinate measuring machine, in accordance with illustrative embodiments. As shown, the user interface 125 may have control buttons 125A and knobs 125B that allow a user to manually operate the CMM 100.

Among other things, the user interface 125 may enable the user to change the position of the measuring device 103 or base 102 (e.g., with respect to one another) and to record data describing the position of the measuring device 103 or base 102.

In addition, the user interface 125 may enable the user to focus a camera (if the measuring device 103/arm 104 includes a camera) on a workpiece or target 111 and record data describing the focus of the camera. In a moving table CMM 100, for example, the measuring device 103 may also be movable via control buttons 125C. As such, the movable features 122 may respond to manual control, or under control of the computing device 130, to move the base 102 and/or the measuring device 103 (e.g., a mechanical probe in a mechanical CMM 100 or a camera in a machine vision CMM 100) relative to one another. Accordingly, this arrangement permits the workpiece 111 being measured to be presented to the measuring device 103 from a variety of angles, and in a variety of positions and orientations.

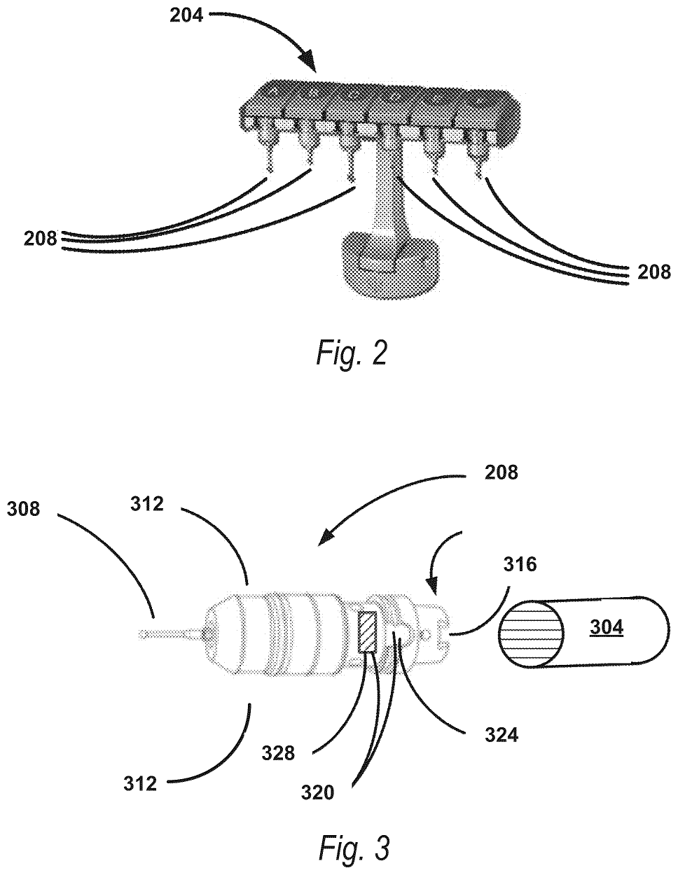

FIG. 2 schematically shows a probe rack 204 in accordance with illustrative embodiments. As shown, the probe rack 204 may store one or more different probes 208 with stylii in general proximity to the CMM 100. That rack may be coupled directly to the CMM 100 or be separate from the CMM 100. Different probes 208 may have different stylus sizes installed or be different types of probes 208. In one embodiment, one or more probes 208 may include multiple stylii. The multiple stylii may have different lengths or physical dimensions or be different types of stylii (e.g., tactile, optical, camera, etc.). The probe rack 204 may provide a uniform way to store the probes 208 in an organized and centralized fashion. Each probe 208 may have its own probe port, and in one embodiment, the probe ports may be equally spaced within the probe rack 204. Each of the probes 208 may be selectively and individually coupled with the movable arm 104 of the CMM 100. As noted above, the probes 208 may be any one of a variety of types of probes 208, such as a mechanical, tactile, or non-contact probe such as an optical probe or camera, to name but a few examples. In operation, any of the probes 208 may be changed, removed from and/or coupled to the movable arm 104 of the CMM 100, either manually by an operator, or robotically by the CMM 100. For example, a probe 208 may be removed from a probe port and coupled to a probe interface 304, as shown in FIG. 3. In one embodiment, probe 208 selection may depend on a workpiece to be measured 111.

FIG. 3 schematically shows a detachable probe 208 in accordance with illustrative embodiments. Some probes 208 may be configured to operate with a specific type of stylus 308. For example, some probes 208 may have an interface 304 that includes one or more sensors 312 to detect deflection of a tactile stylus 308 when that stylus 308 contacts a workpiece 111. Other probes 208 may have an interface 304 (which may be referred to as a “stylus interface”) that includes electronics to receive electrical signals, such as from an optical stylus or multiple stylii, for example. In one embodiment, the probe 208 may twist onto a distal end of the probe interface 304 and may include one or more retention features.

Probes 208 may also include a probe body 312 with a physical interface 316 (to mount to the CMM 100) having a probe indicium 320 to identify a probe physical feature. They indicium 320 may be in the form of the physical feature that uniquely identifies the probe 208, or its type. The corresponding probe interface 304 on the CMM 100, alone or in concert with the computing device 130, may confirm the identity of the probe 208 by sensing the physical feature through the physical interface 316.

In another embodiment, the body 312 of the probe 208 may have a surface feature 324 that uniquely identifies the probe 208, or its type, and which may be detected by the CMM 100, for example, by using a camera. Among other things, the surface feature 324 may include raised text, a color, or recesses in a specified pattern. In another embodiment, the body 312 of the probe 208 may include an identity interface 328 that uniquely identifies the probe 208, or its type. For example, the identity interface 328 may be an optically readable feature such as a bar code, a color, or another optical indicia that may be read by the camera. In other embodiments, the physical interface 316 may be an electrical interface configured to make electrical contact with the CMM 100 and generate an electrical signal with a pattern or signature that uniquely identifies the probe 208. For example, this interface 316 may be a part of the probe interface 304 that couples with the CMM arm 104. In other embodiments, the physical interface 316 may include a transmitter, such as an RFID chip, that transmits an identifier that uniquely identifies the probe 208, for example in response to a query from the CMM 100. In one embodiment, each probe 208 may include a contactless sensor (not shown) within the probe body 312.

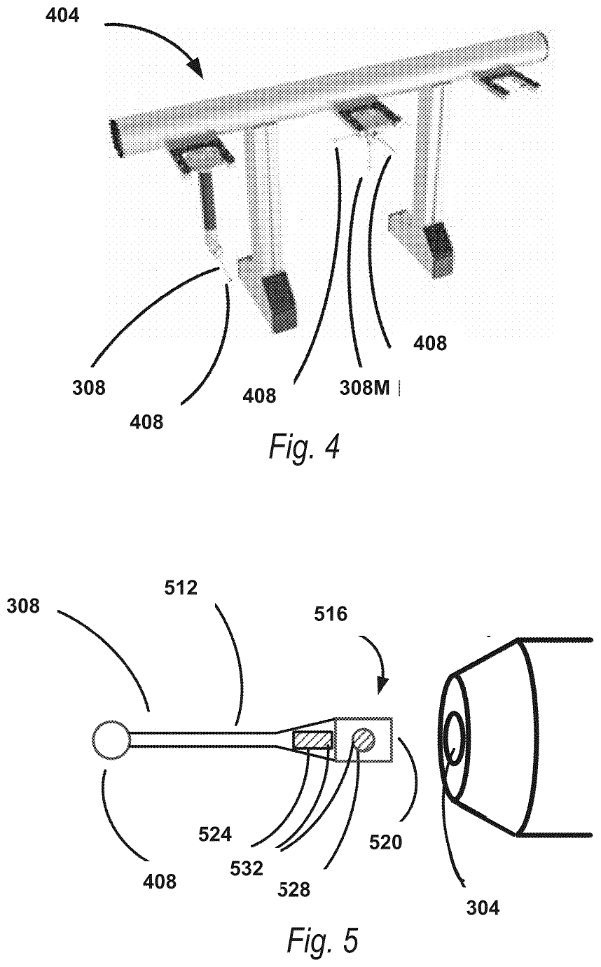

FIG. 4 schematically shows a stylus rack 404 in accordance with illustrative embodiments. Each stylus 308 in the stylus rack 404 may be coupled with a probe 208, and thereby coupled to the movable arm 104 of the CMM 100, and accordingly functions as the above-noted measuring device. Moreover, each stylus 308 may be any one of a variety of types of stylus 308, such as a single-headed stylus 308 having a single stylus tip 408 (e.g., FIG. 5), or a multi-headed-stylus 308M having more than one stylus tip 408, and may be a tactile stylus (e.g., a stylus that measures a workpiece 111 by contacting the workpiece 111), or a non-contact stylus (e.g., a stylus that measures a workpiece 111 without contacting the workpiece 111), to name but a few examples. In operation, a stylus 308/308M may be changed, removed from, and/or coupled to a probe 208, either manually by an operator, or automatically (robotically) by the CMM 100. For example, the stylus 308/308M may be removably coupled to the probe body 312.

FIG. 5 schematically shows another stylus 308 in accordance with illustrative embodiments. As known by those in the art, the stylus 308 includes a body 512 and a stylus tip 408. The stylus 308 mounts to the probe 208 via the probe interface 304 using a physical interface 516. The physical interface 516 may include a physical feature 520 that uniquely identifies the stylus 308. A corresponding stylus interface on the probe 304, alone or in concert with the computing device 130, may confirm an identity of the stylus 308 by sensing the physical feature 520. In one embodiment, a stylus 308 may include a sensor 524. In one embodiment, a stylus 308 may also include one or more forms of indicia 528, 532 other than or in addition to a sensor 524.

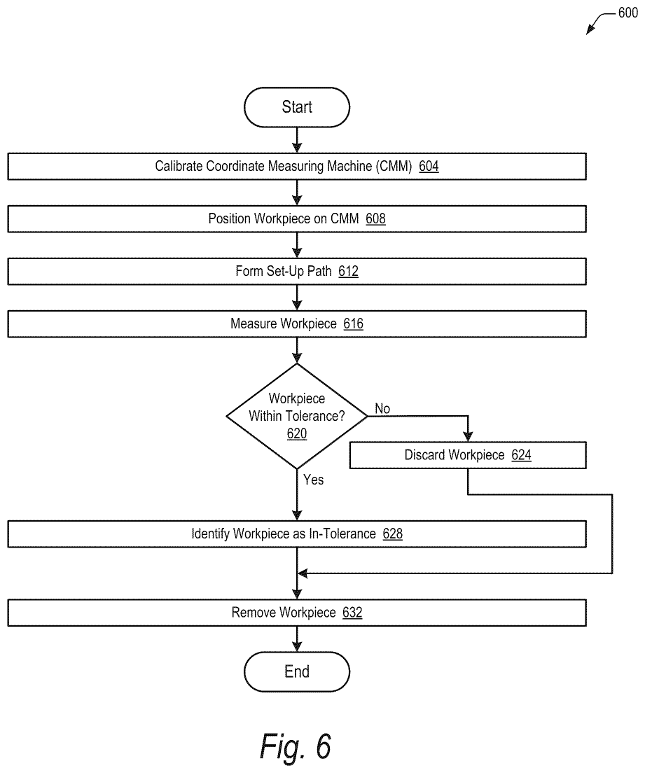

FIG. 6 schematically shows an uncompensated CMM Measurement Process 600 with a tactile stylus 308. Some of the steps shown in FIG. 6 may be performed in a different order than that shown or at the same time. Those skilled in the art therefore can modify the process as appropriate. It also should be noted that reference to an operator performing certain steps is but one of a number of different options. Some embodiments may use a logic device or automated robot to perform some of the steps. Accordingly, discussion of an operator is not intended to limit various embodiments. This process preferably is repeated many times for a plurality of different workpieces 111 manufactured to a same specification. For example, this process may be used to measure hundreds of jet engine blades that nominally are identically manufactured.

The process of FIG. 6 begins at step 604, in which an operator calibrates the CMM 100. More particularly, to accurately measure the workpiece 111, the CMM 100 should have data relating to the actual orientation and position of an optional rotary table (or on the base without a rotary table) on the CMM 100 relative to the other components of the CMM 100. As such, the system may gather data relating to a vector and a position of the axis about which the rotary table rotates. To that end, an operator first may position a substantially straight shaft at the nominal center of the rotary table. Next, the operator may rotate the shaft in pre-specified increments, such as 90 degree increments, and measure the orientation and location of the shaft at each increment. Using well-known CMM calibration routines, this process should enable the CMM 100 to gather data about the actual orientation and location of the rotary table. In other words, this initial calibration process provides the frame of reference of the rotary table to the system. However, this calibration process does not provide temperature compensation for the probe/stylus or stylus 308. Flow proceeds to block 608.

At block 608, after calibrating the CMM 100, the operator positions the workpiece 111 on the rotary table of the CMM 100. At this stage of the process, this workpiece 111 just positioned on the rotary table may be the first of a series of nominally identical workpieces 111 to be measured by the CMM 100. Of course, some embodiments may measure just one workpiece 111, or multiple workpieces 111. Flow proceeds to block 612.

At block 612, a set-up or initial path is formed for performing a first scan of the workpiece 111 on the rotary table. More specifically, as known by those skilled in the art, the workpiece 111 preferably was manufactured based on a set of nominal requirements/specifications identifying its ideal structure. For example, the set of nominal requirements may include geometry information, such as the flatness or waviness of the surface, the size of the workpiece 111, the size and shape of certain features of the workpiece 111, the distances between certain features of the workpiece 111, the orientation of certain features relative to other features of the workpiece 111, etc. This set of nominal specifications and/or geometry may be typically stored in a computer-aided design file (a “CAD” file) in a memory device of the CMM 100 (e.g., in memory in the computing device 130). A jet engine blade is a good example of a workpiece 111 that may benefit from illustrative embodiments. As known by those in the art, a jet engine blade has two large, opposed surfaces, and two very thin edges between the two large, opposed surfaces. As also known by those skilled in the art, the two opposed surfaces often have complex contours and geometries that, despite state-of-the-art manufacturing techniques, often widely vary from the nominal requirements. Such workpieces 111 therefore often have relatively large deviations from the nominal.

In one embodiment, the computing device 130 may form the set-up path by using nominal model data present in a computer-aided design (CAD) file, as well as calibration information identifying the position of the rotary table and other parts of the CMM 100.

Because it is based upon nominal information, the set-up path likely may periodically move the workpiece 111 in and out of the focal plane (i.e., beyond the focal length) of the probe 208 during probe travel. Despite that, the set-up path should be accurate enough for the probe 208 to have a first accuracy that is sufficient for its intended function. In other words, although this first accuracy may not be sufficient to appropriately measure the workpiece 111, it should be sufficient to gather data to ultimately form the actual scan path that will be used to measure the workpiece 111. Flow proceeds to block 616.

At block 616, after generating the scan path, the CMM 100 measures the workpiece 111. To that end, the computing device 130 directs the probe 208 along the calculated scan path(s) to determine the actual measurements of prescribed portions of the workpiece 111. Regardless of whether the workpiece 111 has a discontinuity or not, the CMM 100 may measure some or all of each scan path. In some embodiments, the CMM 100 may measure a same or different part of the workpiece 111 with different stylii of a multi-stylus probe 208. This measurement has a second accuracy that preferably is better than the accuracy of the first scan. Flow proceeds to decision block 620.

It should be noted that some embodiments skip this two-pass method to form the scan path. In that case, the measurement platform uses CAD data of the workpiece 111 and other information to set up a path for a full scan.

At decision block 620, the computing device 130 may compare the measured values to the stored nominal measurements and their permitted tolerances. For example, the distance between two prescribed features on side 1 of the workpiece 111 may nominally be 15 millimeters with a tolerance of 0.5 millimeters. Accordingly, the computing device 130 may determine if the measurements of the workpiece 111 are within tolerances specified by the CAD file. Continuing the immediately prior example, if the distance between the two noted features is 15.6 millimeters, then the workpiece 111 is outside of the permitted tolerances. In that case, flow proceeds to block 624. Conversely, if the workpiece 111 is within specified tolerances (e.g., 15.18 millimeters between the two noted features), then flow proceeds to block 628.

At block 624, the workpiece 111 is not within specified tolerances and the computing device 130 may discard the workpiece 111 and/or note the measurement discrepancy. Flow proceeds to block 632.

At block 628, the computing device 130 identifies the workpiece 111 as being within specified tolerances. Flow proceeds to block 632.

At block 632, an operator or other entity may remove the workpiece 111 from the CMM 100. Flow ends at block 632.

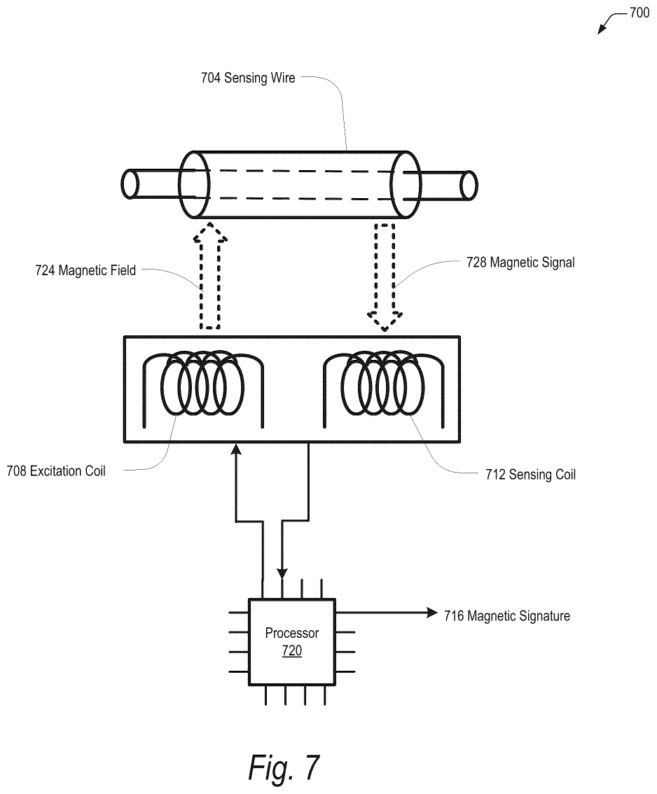

FIG. 7 schematically shows a sensor system 700 that may be used in illustrative embodiments, including in the systems described above. Each probe 208 may include an integral or connected sensing wire 704 producing a unique magnetic signal 728. In one embodiment, the sensor system 700 may include the sensing wire 704 or magnetic sensor and a reader. The reader may include a passive portion and an active portion. The passive portion may include a sensing coil 712 that receives the magnetic signal 728 via magnetic induction and the active portion may include an excitation coil 708 that emits a magnetic field 724 to the sensing wire 704. A multi-stylus probe 208 may only require a single sensing wire 704 to uniquely identify the probe 208. The sensing wire 704 may be made from a metallic alloy core surrounded by an insulator.

Other embodiments may use other devices in lieu of the sensing wire 704. For example, some embodiments may use a permanent magnet, magnetostrictive materials (e.g., using Terfenol-D or Galfenol), other piezomagnetic materials that change their magnetic properties (e.g., magnetization or permeability) when subjected to mechanical stress, magnetic markers, encoded tags, inductive devices with permanent magnets.

In the embodiment shown, the excitation coil 708 and the sensing wire 704 are placed proximate to each other, preferably in a mutual position with an asymmetric magnetic field with respect to the sensing wire 704. For example, depending on the specific sensor chosen, a proximity of between 50-100 mm may be required for reliable detection. Unless present in noisy magnetic or electric fields, the excitation coil 708 may be powered with only a few milliamps. Output from the sensing coil 712 may include magnetic and electrical noise present in the vicinity of the sensing coil 712 during measurement. A processor 720 may filter noise from the received signal and amplify the magnetic signal 728, if needed.

In one embodiment, the processor 720 or another circuit may provide an AC waveform to the excitation coil 708. The sensing wire 704 is within the proximity of the excitation coil 708 such that the sensing wire 704 reacts according to the magnetic field 724 produced by the excitation coil 708. This magnetic field 724 corresponds to the AC waveform. The sensing coil 712 responsively detects the reaction of the sensing wire 704 and provides the magnetic signal 728 to the processor 720. The processor 720 may then digitize the signal as well as filter/amplify the signal. Based on the relationship between the AC waveform and the received magnetic signal 728, the processor 720 may determine a unique ID associated with the sensing wire 704, and hence the corresponding probe 208.

In another embodiment, the processor 720 may provide a number of magnetic signatures 716 to further logic or circuitry coupled to a memory device that stores magnetic signatures 716 for multiple probes 208. In one embodiment, the coils 708, 712 and possibly the processor 720 may be located where a power source may be available, such as a probe rack port or within CMM robotics 104.

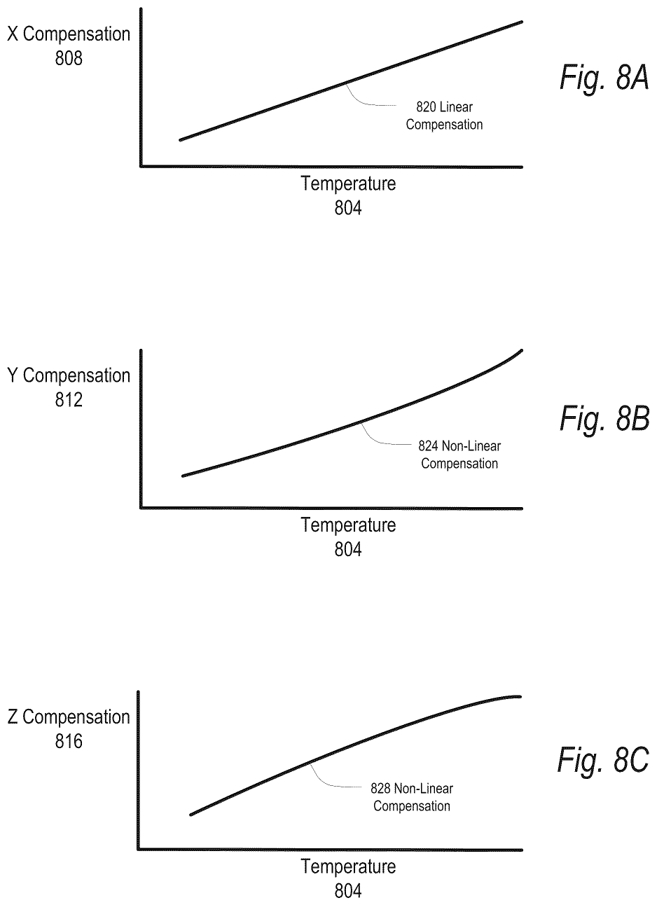

FIG. 8A schematically shows an exemplary x-axis compensation diagram vs. temperature in accordance with illustrative embodiments. Tactile stylii 308 may be constructed from many materials or combination of materials and have different shapes and lengths with one or more tips 408. These different stylii 308 may have unique deflections with respect to temperature. For example, some may deflect in only an x-axis while others may deflect in x, y, and z axes. Additionally, seemingly identical stylii 308 may deflect slightly differently due to material or manufacturing variations. For these reasons, temperature compensation must be performed for each specific stylus 308 in a probe 208 at the time it will be used to measure a workpiece 111. Additionally, the probe 208 itself, whether a tactile or an optical probe 208, may experience minor deflections in the x, y, and/or z axes due to ambient temperature variations.

FIG. 8A illustrates an example of an x-axis compensation 808 as a function of temperature 804 (i.e., the ambient temperature at the stylus 308). The x compensation 808 shows a linear compensation, with the x compensation 808 increasing linearly with increasing temperature 804.

FIG. 8B schematically shows an exemplary y-axis compensation diagram vs. temperature in accordance with illustrative embodiments. FIG. 8B illustrates an example of a y-axis compensation 812 as a function of temperature. The y compensation 812 shows a non-linear compensation, with the y compensation 812 increasing faster than the temperature 804 at elevated temperature 804 values.

FIG. 8C schematically shows an exemplary z-axis compensation diagram vs. temperature in accordance with illustrative embodiments. FIG. 8C illustrates an example of a z-axis compensation 816 as a function of temperature 804. The z compensation 816 shows a non-linear compensation, with the z compensation 816 decreasing faster than the temperature 804 at elevated temperature 804 values.

The graphs in FIGS. 8A-8C may be obtained by routine experimentation. For example, a probe/stylus may be evaluated over an expected temperature range the CMM 100 operates in, such as from 17° C. (62.6° F.) to 27° C. (80.6° F.). The probe/stylus deflection may be measured at discrete ambient temperatures intervals that produce a meaningful deflection. For example, although meaningful deflection may not occur at ¼° C. intervals, meaningful deflection may be observed at ½° C. intervals. Although the graphs themselves may not be stored in a memory as a graph, the data may be stored in a temperature compensation table 900, as explained below.

FIGS. 8A-8C illustrate only a single example of 3-axis temperature compensation for a given probe/stylus, but any probe/stylus may have different temperature compensations than shown. For example, one of or axes may not require temperature compensation due to materials or construction that do not deflect under ambient temperature variations. Additionally, temperature variations may also affect probe/stylus deflections in terms of yaw, roll, and or pitch. Therefore, the compensations to x-axis, y-axis, and/or z-axis values may reflect yaw, roll, or pitch variations as well.

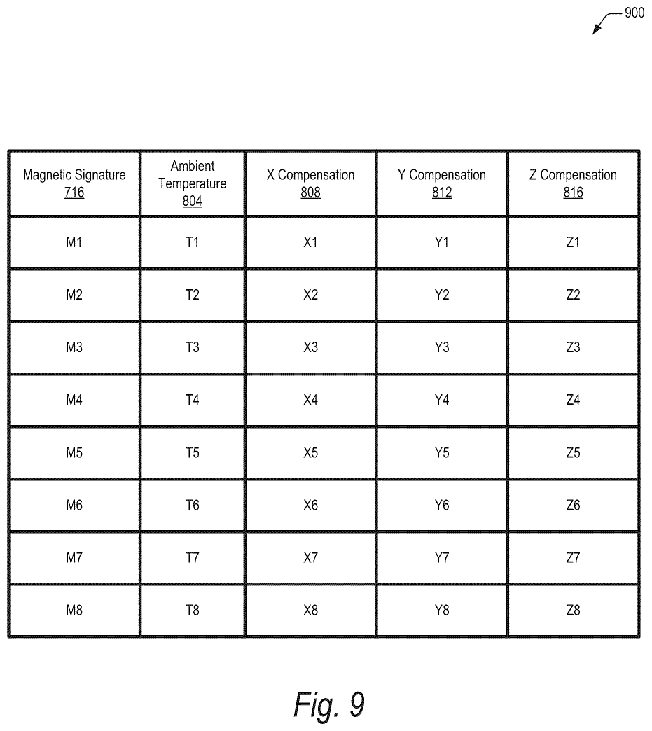

In one embodiment, in lieu of a graphical representation as shown in FIGS. 8A-8C or a table as shown in FIG. 9, curve fit equations may be determined for a given probe/stylus. Separate equations may be used for x, y, and z compensations of the behavior is different as shown in FIGS. 8A-8C.

FIG. 9 shows a probe/stylus compensation table 900 in accordance with illustrative embodiments. Each individual probe/stylus used with a CMM 100 would preferably have its own probe/stylus compensation table 900 prior to using that probe/stylus to accurately measure workpieces 111 since individual samples may have different temperature compensation responses. Multi-stylus probes 208 may either have a number of temperature compensation tables 900, each for a different stylus 308, or a larger stylus compensation table 900 with separate x, y, and z compensations for each stylus 308.

Probe/stylus compensation tables 900 are generated by successively testing each probe/stylus combination at a range of ambient temperatures 804. Initial testing will determine the sensitivity of the stylus 308 to temperature changes. This and the range of ambient temperatures for the CMM 100 will establish the number of rows in the table and the difference in temperature 804 between each pair of rows. The idea is to utilize a temperature 804 granularity where a noticeable x, y, and/or z offset starts to occur. Once a new stylus compensation table 900 is completed for a stylus 308, it is available to be used for temperature compensation.

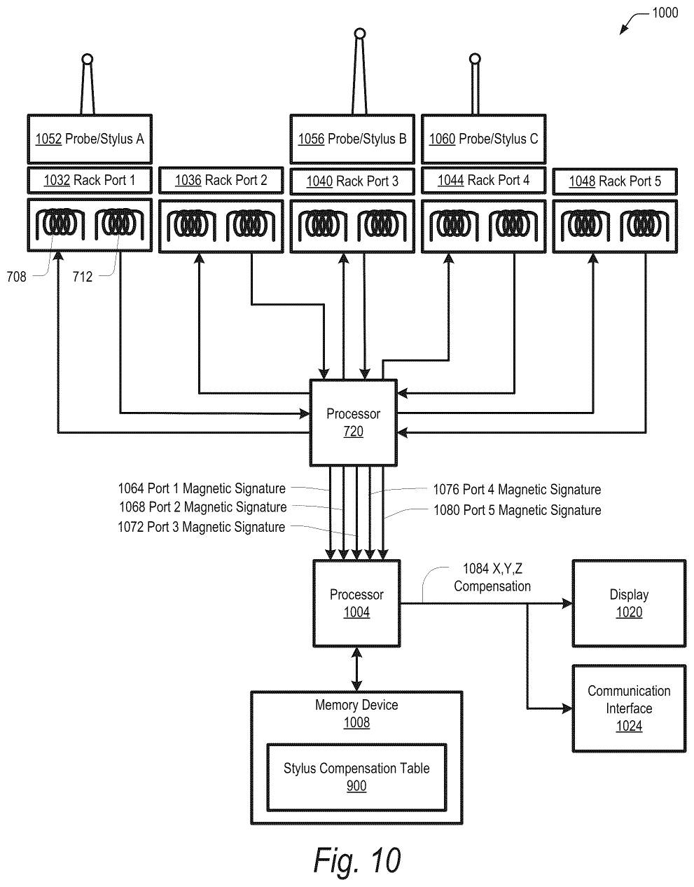

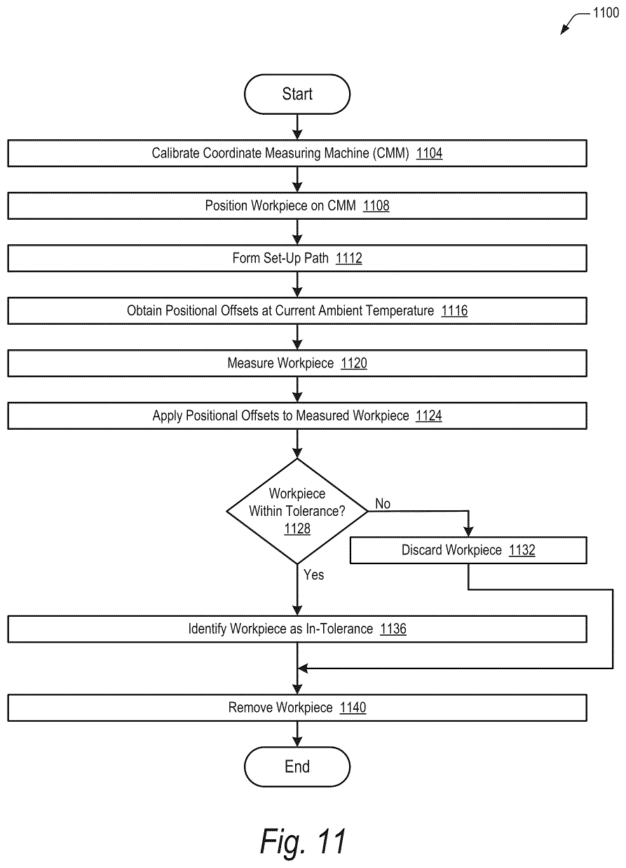

The probe/stylus compensation table 900 may include several entries based on ambient temperature 804. The number of entries may not be fixed between different stylus compensation tables 900 since temperature granularity may affect each probe/stylus combination differently. For example, a first probe/stylus may not experience a noticeable deflection based on temperature at 2 degrees difference while a second probe/stylus may experience a noticeable deflection based on temperature at 0.5 degrees difference. In that case, the probe/stylus compensation table 900 for the second probe/stylus may have four or more times as many temperature 804 entries as the probe/stylus compensation table 900 for the first probe/stylus. FIG. 9 illustrates an example with eight ambient temperature entries 804, identified as T1-T8. This corresponds to eight magnetic signature 716 entries, identified as entries M1-M8, eight x compensation 808 entries, identified as X1-X8, eight y compensation 812 entries, identified as Y1-Y8, and eight z compensation 816 entries, identified as Z1-Z8. In response to receiving a magnetic signature 716 for a specific probe/stylus, a processor 720, 1004, 130 identifies the corresponding probe/stylus compensation table 900 in a memory device 1008 and cross references the magnetic signature 716 to find the corresponding x 808, y 812, and z 816 compensations for the ambient temperature 804 (which corresponds to the magnetic signature 716). This is explained more with reference to FIGS. 10 and 11.

FIG. 10 shows a block diagram of an exemplary probe temperature compensation system 1000 in accordance with illustrative embodiments. As known in the art, a CMM 100 may include and/or use a number of probe racks 204 to store a variety of different types and sizes of probes 208. For example, FIG. 10 illustrates three rack ports containing different sizes, orientation, and configurations of tactile probes/stylii 208.

FIG. 10 illustrates a probe rack system 1000 that includes five rack ports, identified as rack port 1 1032, rack port 2 1036, rack port 3 1040, rack port 4 1044, and rack port 5 1048. Rack port 1 1032 is occupied by probe/stylus A 1052, rack port 3 1040 is occupied by probe/stylus B 1056, and rack port 4 1044 is occupied by probe/stylus C 1060. Probe rack port 2 1036 and probe rack port 5 1048 are currently unoccupied by probes 208. Each of the probes/stylus' 1052, 1056, and 1060 includes a magnetic sensor (e.g., a sensing wire 704).

Associated with each rack port is a reader that includes a pair of coils: an excitation coil 708 providing an active portion of the reader and a sensing coil 712 providing a passive portion of the reader, as shown in FIG. 7. When docked within a rack port, probes 208 are within a sensing distance (sensing proximity) of the coils 708, 712. Prior to being docked in a rack port, the robotic arm 104 may move a captured probe 208 into sensing proximity of an empty rack port or a separate standalone reader separate from probe rack 204 in order for the probe rack system 1000 to reliably detect and identify the captured probe 208. Therefore, preferably the reliable proximity or sensing distance from the coils 708, 712 to a captured probe 208 (by the robotic arm 104) is greater than the docked probe distance (e.g., the distance between docked probe/stylus A 1052 and coils 708, 712). Each input and output to/from the coils 708, 712 is provided to the processor 720. As stated with respect to FIG. 7, the processor 720 may generate AC waveforms to the excitation coils 708 and filter noise and digitize inputs from the sensing coils 712.

In one embodiment (not shown), the same processor 720 may interface with the coils 708, 712 as well as one or more memory devices 1008, communication devices 1024, and/or display devices 1020. In the illustrated embodiment, the processor 720 may provide the digitized magnetic signatures 716 corresponding to each rack port to another processor 1004 that interfaces with a memory device 1008, a display 1020 (and possibly a communication device 1024 to transmit unique temperature compensations 1084 to the CMM 100 or other entity). A magnetic signature 1064 for port 1, a magnetic signature 1068 for port 2, a magnetic signature 1072 for port 3, a magnetic signature 1076 for port 4, and a magnetic signature 1080 for port 5 may be provided to processor 1004. The port 1 magnetic signature 1064 would correspond to probe/stylus A 1052, the port 3 magnetic signature 1072 would correspond to probe/stylus B 1056, and the port 4 magnetic signature 1076 would correspond to probe/stylus C 1060. The port 2 magnetic signature 1068 and the port 5 magnetic signature 1080 would reflect no probe/stylii installed in either ports 1036 or 1048.

In response to the processor 720 generating magnetic signatures or changes to magnetic signatures 716, the processor 1004 may read a stylus compensation table 900 stored in an accessible memory device 1008 to determine a unique temperature compensation 1084 and transmit the unique temperature compensation 1084 to a display 1020 or a communication device 1024. The unique temperature compensation 1084 may include an association between a rack port and a probe 208 or a probe/stylus, such as probe/stylus A 1052, probe/stylus B 1056, or probe/stylus C 1060.

FIG. 11 schematically shows a compensated CMM measurement process 1100 in accordance with illustrative embodiments. The process shown and described with respect to FIG. 11 may be seen as analogous to the process of FIG. 6 but including temperature compensation as well. It should be noted that some of the steps may be performed in a different order than that shown, or at the same time. Those skilled in the art therefore can modify the process as appropriate.

The process of FIG. 11 begins at step 1104, in which an operator calibrates the CMM 100. More particularly, to accurately measure the workpiece 111, the CMM 100 should have data relating to the actual orientation and position of an optional rotary table (or on the base without a rotary table) on the CMM 100 relative to the other components of the CMM 100. As such, the system may gather data relating to a vector and a position of the axis about which the rotary table rotates. To that end, an operator first may position a substantially straight shaft at the nominal center of the rotary table. Next, the operator may rotate the shaft in pre-specified increments, such as 90 degree increments, and measure the orientation and location of the shaft at each increment. Using well-known CMM calibration routines, this process should enable the CMM 100 to gather data about the actual orientation and location of the rotary table. In other words, this initial calibration process provides the frame of reference of the rotary table to the system. However, this calibration process does not provide temperature compensation for the stylus 308. Flow proceeds to block 1108.

At block 1108, after calibrating the CMM 100, the operator positions the workpiece 111 on the rotary table of the CMM 100. At this stage of the process, this workpiece 111 just positioned on the rotary table may be the first of a series of nominally identical workpieces 111 to be measured by the CMM 100. Of course, some embodiments may measure just one workpiece 111, or multiple workpieces 111. Flow proceeds to block 1112.

At block 1112, a set-up or initial path is formed for performing a first scan of the workpiece 111 on the rotary table. More specifically, as known by those skilled in the art, the workpiece 111 preferably was manufactured based on a set of nominal requirements/specifications identifying its ideal structure. For example, the set of nominal requirements may include geometry information, such as the flatness or waviness of the surface, the size of the workpiece 111, the size and shape of certain features of the workpiece 111, the distances between certain features of the workpiece 111, the orientation of certain features relative to other features of the workpiece 111, etc. This set of nominal specifications and/or geometry may be typically stored in a computer-aided design file (a “CAD” file) in a memory device of the CMM 100 (e.g., in memory in the computing device 130). A jet engine blade is a good example of a workpiece 111 that may benefit from illustrative embodiments. As known by those in the art, a jet engine blade has two large, opposed surfaces, and two very thin edges between the two large, opposed surfaces. As also known by those skilled in the art, the two opposed surfaces often have complex contours and geometries that, despite state-of-the-art manufacturing techniques, often widely vary from the nominal requirements. Such workpieces 111 therefore often have relatively large deviations from the nominal.

In one embodiment, the computing device 130 may form the set-up path by using nominal model data present in a computer-aided design (CAD) file, as well as calibration information identifying the position of the rotary table and other parts of the CMM 100.

Because it is based upon nominal information, the set-up path likely may periodically move the workpiece 111 in and out of the focal plane (i.e., beyond the focal length) of the probe 208 during probe travel. Despite that, the set-up path should be accurate enough for the probe 208 to have a first accuracy that is sufficient for its intended function. In other words, although this first accuracy may not be sufficient to appropriately measure the workpiece 111, it should be sufficient to gather data to ultimately form the actual scan path that will be used to measure the workpiece 111. Flow proceeds to block 1116.

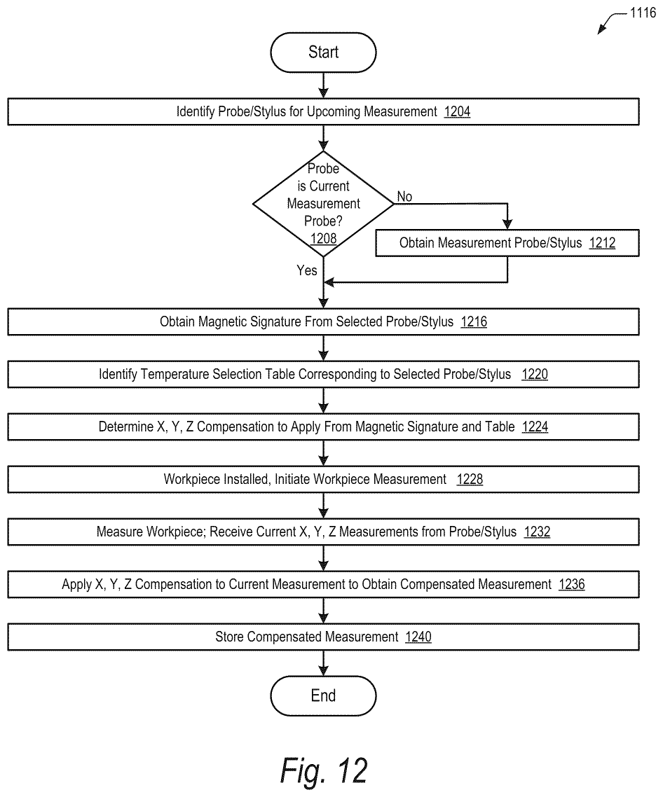

At block 1116, the CMM 100 obtains positional offsets 1084 at the current ambient temperature 804. The details of obtaining the positional offsets 1084 (i.e., temperature compensations) are shown and explained in FIG. 12. In one embodiment, the CMM 100 may obtain positional offsets 1084 for multiple stylii 308 of a multiple stylus probe 208 (with a different temperature compensation table 900 used for each stylus 308). Once the CMM 100 has the positional offsets, flow proceeds to block 1120.

At block 1120, the CMM 100 measures the workpiece 111. To that end, the computing device 130 directs the probe/stylus along the calculated scan path(s) to determine the actual measurements of prescribed portions of the workpiece 111. Regardless of whether the workpiece 111 has a discontinuity or not, the CMM 100 may measure some or all of each scan path. This measurement has a second accuracy that preferably is better than the accuracy of the first scan. Flow proceeds to block 1124.

At block 1124, the CMM 100 (e.g., computing device 130) applies the received positional offsets 1084 to the measurements from the just-measured workpiece 111 performed by the current probe/stylus. Depending on the ambient temperature 804, this may increase some measurements, decrease some measurements, or not affect some measurements (or possibly even all measurements). For example, the current ambient temperature may be a temperature 804 in the corresponding stylus compensation table 900 that serves as a nominal temperature where the materials, etc. in the current probe/stylus do not expand, contract, or deflect. Flow proceeds to decision block 1128.

At decision block 1128, the computing device 130 may compare the measured values to the stored nominal measurements and their permitted tolerances. For example, the distance between two prescribed features on side 1 of the workpiece 111 may nominally be 15 millimeters with a tolerance of 0.5 millimeters. Accordingly, the computing device 130 may determine if the measurements of the workpiece 111 are within tolerances specified by the CAD file. Continuing the immediately prior example, if the distance between the two noted features is 15.6 millimeters, then the workpiece 111 is outside of the permitted tolerances. In that case, flow proceeds to block 1132. Conversely, if the workpiece 111 is within specified tolerances (e.g., 15.18 millimeters between the two noted features), then flow proceeds to block 1136.

At block 1132, the workpiece 111 is not within specified tolerances and the computing device 130 may discard the workpiece 111 and/or note the measurement discrepancy. Flow proceeds to block 1140.

At block 1136, the computing device 130 identifies the workpiece 111 as being within specified tolerances. Flow proceeds to block 1140.

At block 1140, an operator or other entity may remove the workpiece 111 from the CMM 100. Flow ends at block 1140.

FIG. 12 schematically shows an obtain positional offsets at a current ambient temperature process 1116 in accordance with illustrative embodiments. Before workpiece 111 measurements are final, the positional offsets 1084 for the current probe/stylus must be determined and used to modify the workpiece 111 measurements.

The process begins at step 1204, where the current probe/stylus (e.g., a stylus 308 possibly already mounted to a probe 208 but not yet used to make workpiece 111 measurements) is identified. In one embodiment, the probe/stylus may be identified by an indicia or other marking 328, 524, 532 on a probe 208 or a stylus 308 that is either machine-read or input to the computing device 130 by an operator. In one embodiment, if a probe 208 has multiple stylii 308 installed, the identification may not reflect each of the stylii 308. Flow proceeds to decision block 1208.

At decision block 1208, the processor 1004 determines if the probe 208 is a current measurement probe 208 (i.e., already mounted to a robotic arm 104). A stylus 308 must be mounted to a measurement probe 208 prior to measuring a workpiece 111. If the identified probe/stylus is not currently mounted, then flow proceeds to block 1212. If the probe/stylus is currently mounted, then flow instead proceeds to block 1216.

At block 1212, the CMM 100 and robotic arm 104 or an operator obtains the probe/stylus and mounts the probe/stylus. Flow proceeds to block 1216.

At block 1216, the system obtains a magnetic signature 716 from the mounted probe/stylus. This may be performed as detailed in FIG. 10 or other process that brings the magnetic sensor into sensing proximity of the reader coils 708, 712. Flow proceeds to block 1220.

At block 1220, the probe/stylus identification may be provided to the processor 1004 though the communication interface 1024 and the processor 1004 may select a probe/stylus compensation table 900 in the memory device 1008 based on the identification. In another embodiment, the probe/stylus may be identified automatically by bringing the probe/stylus into sensing proximity of an active/passive sensor as shown in FIG. 7 (e.g., in a multi-port probe rack 204 or a standalone reader). As discussed with respect to FIGS. 8 and 9, multiple probe/stylus compensation tables 900, one large stylus compensation table 900, or certain temperature compensation equations may be consulted for a probe 208 having multiple stylii 308. Flow proceeds to block 1224.

At block 1224, the processor 1004 determines x 808, y 812, and z 816 compensations to apply from the magnetic signature 716 and the stylus compensation table 900, as detailed in FIGS. 8 and 9. In illustrative multiple stylus 308 embodiments, this determination may produce separate x 808, y 812, and z 816 compensations for each stylus 308. Flow proceeds to block 1228.

At block 1228, the workpiece 111 is installed to the CMM 100 (i.e., CMM 100 already configured) and workpiece 111 measurements are initiated either automatically or by an operator. The workpiece 111 measurements may include one measurement per workpiece 111 or multiple measurements. In one embodiment, only one workpiece 111 is measured before the probe/stylus is recalibrated by determining if the positional offsets 1084 have changed. In another embodiment, multiple workpieces 111 are measured before the probe/stylus is recalibrated. The determining factor may be the ambient temperature 804 in proximity to the CMM 100, and more importantly, the current probe/stylus being used for measurements. Flow proceeds to block 1232.

At block 1232, the workpiece(s) 111 is/are measured and the CMM 100 (i.e., computing device 130) receives current x, y, and z measurements for the probe/stylus as applied to the workpiece 111. Flow proceeds to block 1236.

At block 1236, the temperature compensated x, y, and z positional offsets 1084 are applied to the current x, y, and z measurements from the probe/stylus to obtain temperature compensated measurements for the workpiece 111. For multiple stylii 308 probes, the CMM 100 applies the proper x, y, and z positional offsets 1084 that correspond to the stylus 308 about to be used. Flow proceeds to block 1240.

At block 1240, the temperature-compensated measurements are stored in a memory device 130, 1208 or a database accessible to the system. Over time, all temperature-compensated measurements for one workpiece 111 or a group of workpieces 111 are stored for later retrieval. Preferably, the above steps should be repeated each time a new stylus 308 is mounted to the probe 208 or a new probe 208 is used for new measurements. Flow ends at block 1240.

Illustrative embodiments discuss a specific magnetic sensor (e.g., that shown in FIG. 7). Illustrative embodiments may apply to other magnetic sensors, such as simple magnets or magnetic security tags. Accordingly, discussion of a specific magnetic sensor is illustrative and not intended to limit various other embodiments.

Various embodiments of the invention may be implemented at least in part in any conventional computer programming language. For example, some embodiments may be implemented in a procedural programming language (e.g., “C”), or in an object oriented programming language (e.g., “C++”). Other embodiments of the invention may be implemented as a pre-configured, stand-alone hardware element and/or as preprogrammed hardware elements (e.g., application specific integrated circuits, FPGAs, and digital signal processors), or other related components.

In an alternative embodiment, the disclosed apparatus and methods (e.g., see the various flow charts described above) may be implemented as a computer program product for use with a computer system. Such implementation may include a series of computer instructions fixed either on a tangible, non-transitory medium, such as a computer readable medium (e.g., a diskette, CD-ROM, ROM, solid state drive, or fixed disk). The series of computer instructions can embody all or part of the functionality previously described herein with respect to the system.

Those skilled in the art should appreciate that such computer instructions can be written in a number of programming languages for use with many computer architectures or operating systems. Furthermore, such instructions may be stored in any memory device, such as semiconductor, magnetic, optical or other memory devices, and may be transmitted using any communications technology, such as optical, infrared, microwave, or other transmission technologies.

Among other ways, such a computer program product may be distributed as a removable medium with accompanying printed or electronic documentation (e.g., shrink rapped software), preloaded with a computer system (e.g., on system ROM or fixed disk), or distributed from a server or electronic bulletin board over the network (e.g., the Internet or World Wide Web). In fact, some embodiments may be implemented in a software-as-a-service model (“SAAS”) or cloud computing model. Of course, some embodiments of the invention may be implemented as a combination of both software (e.g., a computer program product) and hardware. Still other embodiments of the invention are implemented as entirely hardware, or entirely software.

Various embodiments of the invention have been described in fulfillment of the various objectives of the invention. It should be recognized that these embodiments are merely illustrative of the principles of the present invention. Numerous modifications and adaptions thereof will be readily apparent to those skilled in the art without departing from the spirit and scope of the present invention as defined in the following claims.

What is claimed is:

1. A measurement probe temperature compensation system for a coordinate measurement machine, the system, comprising:
a measurement probe configured to measure a workpiece on the coordinate measurement machine; and
a magnetic sensor associated with the measurement probe, the measurement probe having a plurality of positional offsets at a plurality of different ambient temperatures, the magnetic sensor configured to emit a magnetic signal based on a current ambient temperature in response to receipt of a magnetic field.

2. The measurement probe temperature compensation system of claim 1, further comprising a reader configured to receive the magnetic signal and convert the magnetic signal into a magnetic signature, the reader configured to determine a determined positional offset of the probe as a function of the magnetic signature, the determined positional offset being one of the plurality of positional offsets.

3. The measurement probe temperature compensation system of claim 2, wherein the reader comprises a coil to detect the magnetic signal.

4. The measurement probe temperature compensation system of claim 3, wherein the reader is configured to determine a current positional offset of the probe in response to the magnetic sensor is proximate to the coil.

5. The measurement probe temperature compensation system of claim 2, wherein the reader comprises:
a passive portion configured to receive the magnetic signal; and
an active portion configured to emit the magnetic field toward the magnetic sensor.

6. The measurement probe temperature compensation system of claim 5, wherein the active portion uses magnetic induction to produce the magnetic signal received by the passive portion.

7. The measurement probe temperature compensation system of claim 2, wherein the reader comprises:
a memory device, configured to store the plurality of positional offsets cross referenced to a plurality of magnetic signatures for the probe, wherein each positional offset corresponds to a magnetic signature at a different ambient temperature; and
a processor, coupled to the memory device.

8. The measurement probe temperature compensation system of claim 7, wherein the processor is configured to determine a current positional offset for the magnetic signature, wherein the current positional offset corresponds to the current ambient temperature.

9. The measurement probe temperature compensation system of claim 8, wherein the processor communicates the current positional offset to the coordinate measurement machine, and in response the coordinate measurement machine adjusts measurement data of the workpiece by the current positional offset.

10. The measurement probe temperature compensation system of claim 8, wherein the current positional offset comprises one or more of an x-axis, a y-axis, or a z-axis amount.

11. A method of determining a temperature compensation offset for a coordinate measurement machine, the method comprising:
providing a measurement probe comprising a magnetic sensor, the measurement probe configured to be used with the coordinate measurement machine; and
emitting a magnetic field toward the measurement probe to cause the measurement probe to produce a magnetic signal in response to receipt of the magnetic field, the measurement probe having a plurality of positional offsets at a plurality of different ambient temperatures.

12. The method of claim 11, further comprising:
receiving, by a reader, the magnetic signal;
converting, by the reader, the magnetic signal into a magnetic signature;
determining, by the reader, a determined positional offset of the probe as a function of the magnetic signature, the determined positional offset being one of the plurality of positional offsets.

13. The method of claim 12, wherein the reader comprises a coil to detect the magnetic signal.

14. The method of claim 13, comprising:
determining a current positional offset of the probe in response to the magnetic sensor is proximate to the coil.

15. The method of claim 12, wherein the magnetic reader comprises:
a passive portion configured to receive the magnetic signal; and
an active portion configured to emit the magnetic field toward the magnetic sensor.

16. The method of claim 15, wherein
the active portion uses magnetic induction to produce the magnetic signal received by the passive portion.

17. The method of claim 12, wherein the reader comprises:
a memory device, configured to store the plurality of positional offsets cross referenced to a plurality of magnetic signatures for the probe, wherein each positional offset corresponds to a magnetic signature at a different ambient temperature; and
a processor, coupled to the memory device.

18. The method of claim 17, further comprising:
determining, by the processor, a current positional offset corresponding to the current ambient temperature for the magnetic signature.

19. The method of claim 18, further comprising:
communicating, by the processor, the current positional offset to the coordinate measurement machine, and in response:
adjusting, by the coordinate measurement machine, measurement data of the workpiece by the current positional offset.

20. The method of claim 18, wherein the current positional offset comprises one or more of an x-axis, a y-axis, or a z-axis amount.

21. A computer program product for use on a computer system for determining a temperature compensation offset for a measurement probe of a coordinate measurement machine, the computer program product comprising a tangible, non-transient computer usable medium having computer readable program code thereon, the computer readable program code comprising:
program code for causing emission of a magnetic field toward a magnetic sensor of the measurement probe to cause the magnetic sensor to produce a magnetic signal; and
program code for converting the magnetic signal into a magnetic signature, the measurement probe having a plurality of positional offsets at a plurality of different ambient temperatures.

22. The computer program product of claim 21, wherein the program code determines the plurality of positional offsets in response to the magnetic sensor is proximate to a coil.
